(19) United States
(12) Patent Application Publication
(10) Pub. No.: US 2026/0169394 A1
(43) Pub. Date: Jun. 18, 2026

(54) SYSTEM AND METHOD FOR SPECTROSCOPIC CRITICAL DIMENSION MEASUREMENT WITH TWO-DIMENSIONAL DETECTOR ASSEMBLY

(71) Applicant: KLA Corporation, Milpitas, CA (US)

(72) Inventors: Ming DI, Pleasanton, CA (US); Shankar KRISHNAN, Cupertino, CA (US); Dawei HU, Milpitas, CA (US); Jihyun Jade KANG, Fremont, CA (US); Han CHEN, Fremont, CA (US)

(21) Appl. No.: 19/361,963

(22) Filed: Oct. 17, 2025

Related U.S. Application Data
(60) Provisional application No. 63/734,186, filed on Dec. 16, 2024.

(51) Int. Cl. G03F 7/00; G01J 3/02; G01J 3/28; G01N 21/21; G01N 21/95

(52) U.S. Cl. CPC G03F 7/70625; G01J 3/0208; G01J 3/0275; G01J 3/2803; G01N 21/211; G01N 21/9501; G03F 7/706849; G03F 7/706851; G01J 2003/2813; G01N 2021/213

(57) ABSTRACT

The system includes a light source configured to emit light to illuminate a workpiece, an optical subsystem including one or more lenses, mirrors, and diffraction gratings configured to direct and manipulate the light reflected by the workpiece, and a detector assembly configured to detect the light reflected by the workpiece. The detector assembly includes a two-dimensional sensor array and a two-dimensional microlens array, and each sensor is configured to independently generate measurement data based on the light transmitted through the two-dimensional microlens array. The system further includes a processor configured to receive the measurement data from each sensor and a corresponding location of each sensor in the two-dimensional sensor array and determine a spectroscopic critical dimension (SCD) of the workpiece based on the measurement data generated across the two-dimensional sensor array and the corresponding location of each sensor.

### CROSS-REFERENCE TO RELATED APPLICATIONS

This application claims priority to U.S. Provisional Application No. 63/734,186, filed Dec. 16, 2024, the entire disclosure of which is hereby incorporated by reference.

### FIELD OF THE DISCLOSURE

This disclosure relates to semiconductor metrology tools and, more particularly, to spectroscopic ellipsometry (SE) tools and spectral reflectometry (SR) tools.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor workpiece (e.g., wafer, substrate, display panel, etc.) using a large number of fabrication processes to form various features and multiple levels of the semiconductor devices. For example, lithography is a semiconductor fabrication process that involves transferring a pattern from a reticle to a photoresist arranged on a semiconductor workpiece. Additional examples of semiconductor fabrication processes include, but are not limited to, chemical-mechanical polishing (CMP), etch, deposition, and ion implantation. Multiple semiconductor devices may be fabricated in an arrangement on a single semiconductor workpiece that are separated into individual semiconductor devices.

Inspection processes are used at various steps during semiconductor manufacturing to detect defects on workpieces to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

Metrology processes are also used at various steps during semiconductor manufacturing to monitor and control the process. Metrology processes are different than inspection processes in that, unlike inspection processes in which defects are detected on workpieces, metrology processes are used to measure one or more characteristics of the workpieces that cannot be determined using existing inspection tools. Metrology processes can be used to measure one or more characteristics of workpieces such that the performance of a process can be determined from the one or more characteristics. For example, metrology processes can measure a dimension (e.g., line width, thickness, etc.) of features formed on the workpieces during the process. In addition, if the one or more characteristics of the workpieces are unacceptable (e.g., out of a predetermined range for the characteristic(s)), the measurements of the one or more characteristics of the workpieces may be used to alter one or more parameters of the process such that additional workpieces manufactured by the process have acceptable characteristic(s).

Currently, the leading-edge spectroscopic critical dimension (SCD) measurement done through film metrology tools is based on spectroscopic ellipsometry (SE). This in general includes a series of reflective optics, two compensators for extracting all 16 terms of the Mueller matrix, followed by a one-dimensional Charge-Coupled Device (CCD) for the light detection. For a standard ultraviolet (UV) to visible light photodiode array (PDA), this CCD registers the post-grating light intensity at continuous wavelengths, ranging from 190 nm to 860 nm. An optional Infrared spectroscopic ellipsometer (IRSE) CCD, detecting polarized light intensity in the range from about 900 nm to 2500 nm is also available. In addition to SE measurement, SR (spectral reflectometry) measurements are also integrated into the current metrology tools. SR is similar to SE in design, with one key difference being the angle of incident light into the wafer, around 0 degrees for the SR, compared to a much larger angle of incidence (AOI) for SE.

A one-dimensional CCD offers a limited amount of information, as the photons are primarily from the AOI direction. For example, an incoming SE chief ray passing through a first compensator and reflecting off the wafer defines the AOI plane. Any photon reflected off the wafer that deviates from the path of the chief ray due to diffraction or else, is likely lost. This is because the information from some of these photons has different paths along the SE optics and will not register on the one-dimensional CCD. When encountering CD structures on the wafer, diffraction of the incident photons is quite common.

Therefore, what is needed is an improved detector assembly to more robustly capture deviating photons for SCD measurements.

### BRIEF SUMMARY OF THE DISCLOSURE

An embodiment of the present disclosure provides a system. The system may comprise a light source configured to emit light to illuminate a workpiece. The system may further comprise an optical subsystem including one or more lenses, mirrors, and diffraction gratings configured to direct and manipulate the light reflected by the workpiece. The system may further comprise a detector assembly configured to detect the light reflected by the workpiece. The detector assembly may comprise a two-dimensional sensor array and a two-dimensional microlens array, and each sensor may be configured to independently generate measurement data based on the light transmitted through the two-dimensional microlens array. The system may further comprise a processor in electronic communication with the detector assembly. The processor may be configured to receive the measurement data from each sensor and a corresponding location of each sensor in the two-dimensional sensor array. The processor may be further configured to determine a spectroscopic critical dimension (SCD) of the workpiece based on the measurement data generated across the two-dimensional sensor array and the corresponding location of each sensor.

In some embodiments, the detector assembly may further comprise a substrate. The two-dimensional sensor array may be disposed on or at least partially embedded in the substrate.

In some embodiments, the detector assembly may further comprise a glass panel. The two-dimensional microlens array may be defined in the glass panel.

In some embodiments, the two-dimensional microlens array may be coupled to the two-dimensional sensor array.

In some embodiments, the two-dimensional microlens array may be separated from the two-dimensional sensor array.

In some embodiments, the two-dimensional sensor array may comprise at least 500 by 500 sensors.

In some embodiments, a ratio of a number of sensors in the two-dimensional sensor array to a number of microlenses in the two-dimensional microlens array may be 1 to 1.

In some embodiments, a ratio of a number of sensors in the two-dimensional sensor array to a number of microlenses in the two-dimensional microlens array may be at least 4 to 1.

In some embodiments, each sensor of the two-dimensional sensor array may be a charge coupled device (CCD) or a complementary metal oxide semiconductor (CMOS) sensor.

In some embodiments, each sensor of the two-dimensional sensor array may be a tricolor RGB sensor.

In some embodiments the processor may be further configured to determine azimuth angle and angle of incidence information based on the measurement data generated across the two-dimensional sensor array and the corresponding location of each sensor.

In some embodiments, the optical subsystem may further comprise one or more compensators configured to polarize the light emitted by the light source. The detector assembly may be further configured to detect changes in polarization state of the light reflected by the workpiece, including amplitude ratio and phase difference, across a spectrum of wavelengths. The measurement data may comprise spectroscopic ellipsometry data including the changes in polarization state.

In some embodiments, the detector assembly may be further configured to detect an intensity of the light reflected by the workpiece as a function of wavelength. The measurement data may comprise spectroscopic reflectometry data including the intensity of the light reflected by the workpiece across a wavelength range.

Another embodiment of the present disclosure provides a method. The method may comprise emitting, with a light source, light to illuminate a workpiece. The method may further comprise directing, with an optical subsystem, the light through one or more lenses, mirrors, and diffraction gratings. The method may further comprise detecting, with a detector assembly, the light reflected by the workpiece. The detector assembly may comprise a two-dimensional sensor array and a two-dimensional microlens array, and each sensor may be configured to independently generate measurement data based on the light transmitted through the two-dimensional microlens array. The method may further comprise receiving, with a processor, the measurement data from each sensor and a corresponding location of each sensor in the two-dimensional sensor array. The method may further comprise determining, with the processor, a spectroscopic critical dimension (SCD) of the workpiece based on the measurement data generated across the two-dimensional sensor array and a corresponding location of each sensor.

In some embodiments, the step of detecting, with the detector assembly, the light reflected by the workpiece may comprise detecting changes in polarization state of the light reflected by the workpiece, including amplitude ratio and phase difference, across a spectrum of wavelengths. The measurement data may comprise spectroscopic ellipsometry data including the changes in polarization state.

In some embodiments, the step of detecting, with the detector assembly, the light reflected by the workpiece may comprise detecting an intensity of the light reflected by the workpiece as a function of wavelength. The measurement data may comprise spectroscopic reflectometry data including the intensity of the light reflected by the workpiece across a wavelength range.

In some embodiments, a ratio of a number of sensors in the two-dimensional sensor array to a number of microlenses in the two-dimensional microlens array may be 1 to 1.

In some embodiments, a ratio of a number of sensors in the two-dimensional sensor array to a number of microlenses in the two-dimensional microlens array may be at least 4 to 1.

In some embodiments, each sensor of the two-dimensional sensor array may be a charge coupled device (CCD) or a complementary metal oxide semiconductor (CMOS) sensor.

In some embodiments, each sensor of the two-dimensional sensor array may be a tricolor RGB sensor.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of a system according to an embodiment of the present disclosure;

FIG. 2 is a diagram of a system according to another embodiment of the present disclosure;

FIG. 3 is a diagram of a detector assembly according to an embodiment of the present disclosure;

FIG. 4 is an exploded detail view of a detector assembly according to an embodiment of the present disclosure;

FIG. 5 is a cross-sectional view of a pixel of a detector assembly according to an embodiment of the present disclosure;

FIG. 6 is a detail view of four pixels of a detector assembly according to an embodiment of the present disclosure;

FIG. 7 is a flowchart of a method according to an embodiment of the present disclosure;

FIG. 8 is a flowchart of a method according to another embodiment of the present disclosure; and

FIG. 9 is a flowchart of a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

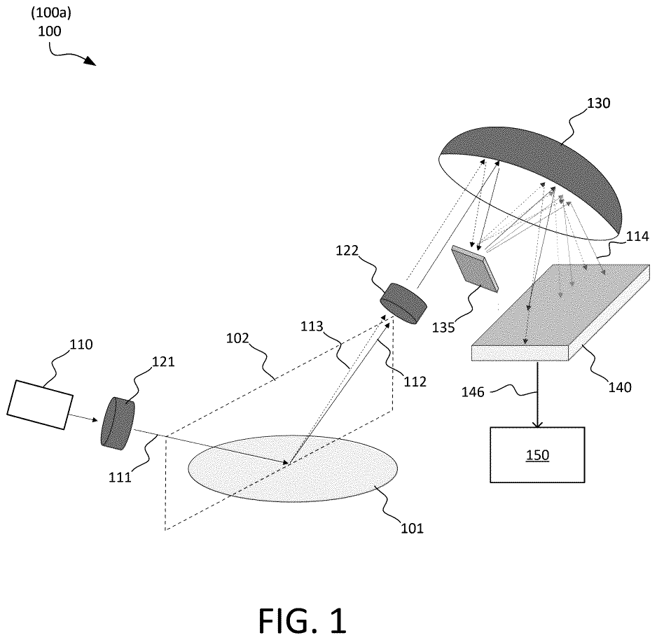

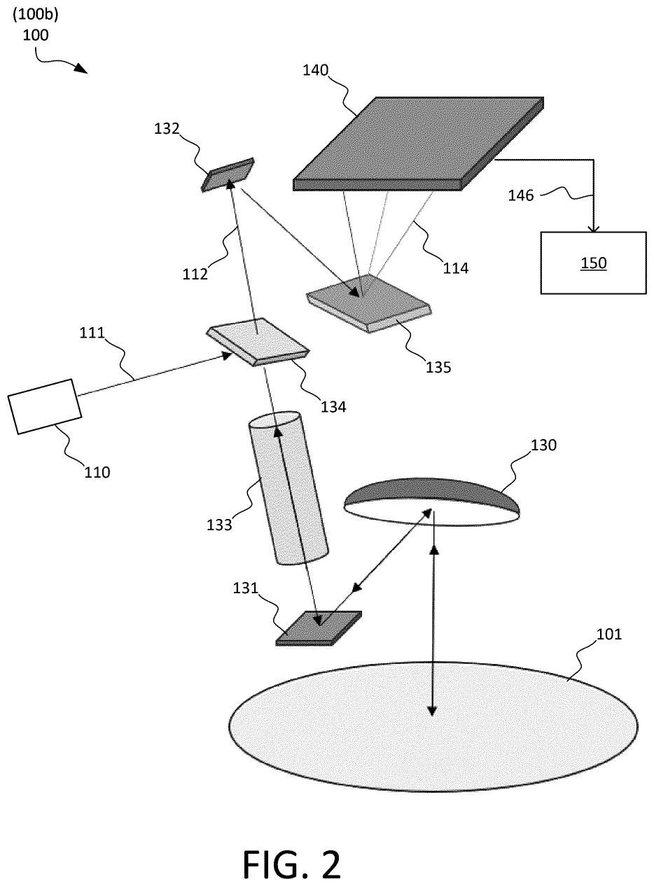

An embodiment of the present disclosure provides a system 100. The system 100 may be a metrology tool configured to measure one or more parameters of a workpiece 101. The workpiece 101 may be, for example, a semiconductor wafer, substrate, printed circuit board (PCB), integrated circuit (IC), chip, flat panel display (FPD), or other type of workpiece. The workpiece 101 may be disposed on a stage (not shown). In some embodiments, the system 100 may be a spectroscopic ellipsometry (SE) tool 100a, as shown in FIG. 1. In some embodiments, the system 100 may a spectroscopic reflectometry (SR) tool 100b, as shown in FIG. 2. Other arrangements of the system 100 for spectroscopic critical dimension (SCD) measurements are possible.

The system 100 may comprise a light source 110. The light source 110 may be configured to emit light 111 to illuminate the workpiece 101. The light source 110 may be selected based on the type of metrology tool (e.g., an SE tool 100a, an SR tool 100b, or other type of tool) and the type of workpiece 101 in order to measure one or more parameters of the workpiece 101. In an instance, the light source 110 may be a laser-driven Xe light source.

The system 100 may further comprise an optical subsystem. The optical subsystem may comprise one or more lenses, mirrors, beam splitters, polarizers, compensators, filters, diffraction gratings, optical slits, or other optical elements configured to direct and manipulate the light 111 emitted by the light source 110 and light 112 reflected by the workpiece 101. The angle of the incident light 111 and the angle of the light 112 reflected by the workpiece 101 may define the AOI plane 102.

In the embodiment shown in FIG. 1, the optical subsystem comprises a first compensator 121 positioned in the path of the light 111 emitted by the light source 110 and a second compensator 122 positioned in the path of the light 112 reflected by the workpiece 101. The first compensator 121 and the second compensator 122 may be configured to polarize the light 111 emitted by the light source 110 and the light 112 reflected by the workpiece 101, respectively. The optical subsystem may further comprise a collection mirror 130 disposed on the path of the light 112 reflected by the workpiece 101. The collection mirror 130 may be configured to collect the light 112 reflected by the workpiece 101, including a chief ray and any diffracted rays 113. The optical subsystem may further comprise a diffraction grating 135. The diffraction grating 135 may be configured to disperse the light reflected by the workpiece 101. In some embodiments, the diffraction grating 135 may be replaced with a prism that separates different wavelengths of light. The optical subsystem of an SE tool 110a may further comprise other optical elements not illustrated in FIG. 1.

In the embodiment shown in FIG. 2, the optical subsystem comprises a beam splitter 134 positioned in the path of the light 111 emitted by the light source 110. The beam splitter 134 may be configured to direct the light 111 from the light source 110 through a tube lens 133 to a first mirror 131 and to the collection mirror 130 to illuminate the workpiece 101. The collection mirror 130 may be further configured to collect the light 112 reflected by the workpiece 101 and direct the light 112 reflected by the workpiece 101 back to the first mirror 131, and through the tube lens 133 and the beam splitter 134. The optical subsystem may further comprise a second mirror 132 disposed in the path of the light 112 reflected by the workpiece 101. The second mirror 132 may be configured to direct the light reflected by the workpiece 101 to the diffraction grating 135. The optical subsystem of an SR tool 100b may further comprise other optical elements not illustrated in FIG. 2, such as, for example, a shutter, Rochon polarizer, optical slits, or others.

The system 100 may further comprise a detector assembly 140. The detector assembly 140 may be configured to detect the light 112 reflected by the workpiece 101. In particular, the detector assembly 140 may be configured to detect the dispersed light 114 from the diffraction grating 135. The diffraction grating 135 may be configured to separate the different wavelengths of the light 112 reflected by the workpiece 101 into distinct beams at different angles. Thus, the location of where the dispersed light 114 is detected by the detector assembly 140 may indicate the spectral composition of the light 112 reflected by the workpiece 101. The detector assembly 140 may be configured to generate measurement data 146 based on the dispersed light 114 detected from the diffraction grating 135.

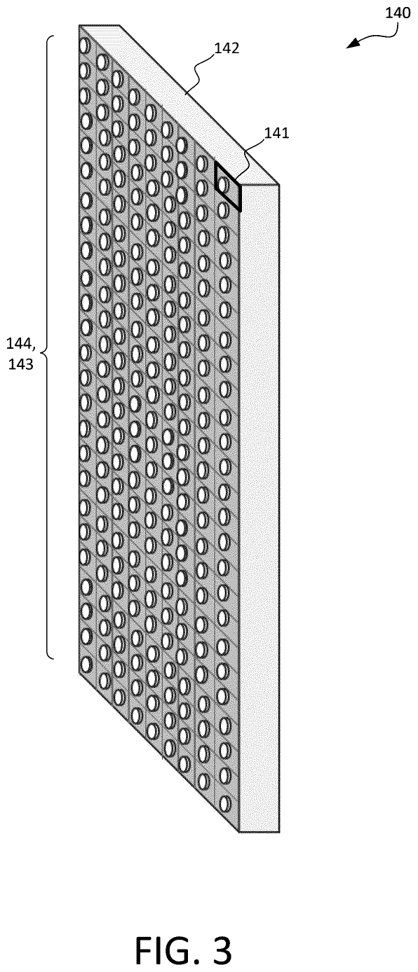

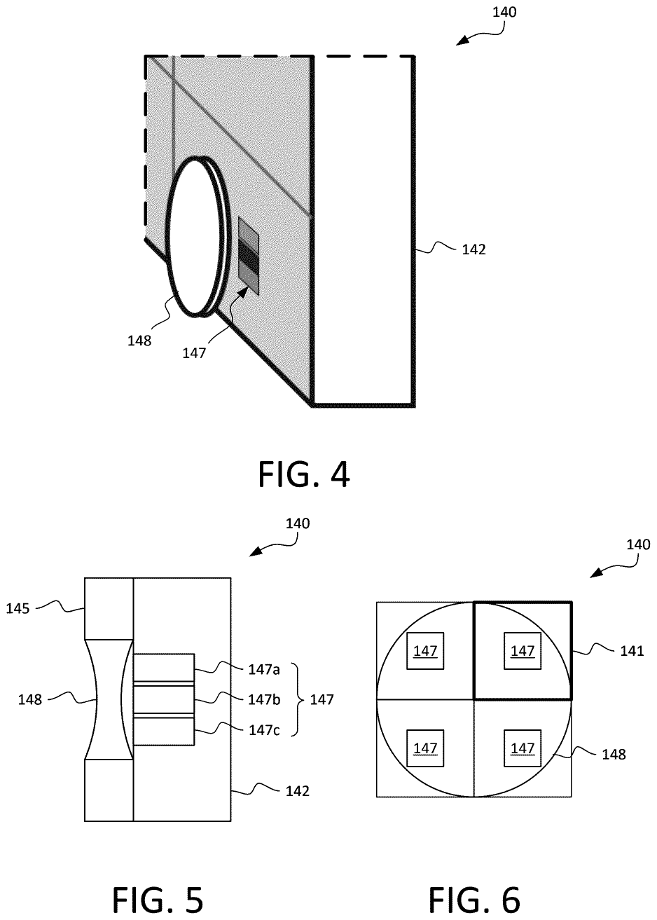

As shown in FIG. 3 and FIG. 4, the detector assembly 140 may comprise a two-dimensional sensor array 144 and a two-dimensional microlens array 143. Each sensor 147 of the two-dimensional sensor array 144 may be configured to independently generate measurement data 146 based on the light 114 transmitted through the two-dimensional microlens array 143. A single pixel 141 of the detector assembly 140 may correspond to a single sensor 147. In some embodiments, the two-dimensional sensor array 144 may comprise thousands of sensors 147 (i.e., thousands of pixels). For example, the two-dimensional sensor array 144 may comprise at least 500 by 500 sensors 147 (i.e., at least 500 by 500 pixels). In some embodiments, each sensor 147 of the two-dimensional sensor array 144 may be a charge coupled device (CCD) or a complementary metal oxide semiconductor (CMOS) sensor. In some embodiments, each sensor 147 of the two-dimensional sensor array 144 may be a tricolor RGB sensor. For example, as shown in FIG. 5, a tricolor RBG sensor may include a red sensor 147a, a green sensor 147b, and a blue sensor 147c in a single sensor package. In some embodiments, each sensor 147 of the two-dimensional sensor array 144 may be configured to simultaneously collect photons and generate measurement data 146. With the sensors 147 being arranged in a two-dimensional array, previously lost diffracted photons may now be captured. Compared to a one-dimensional sensor array, the two-dimensional sensor array 144 may exponentially increase the volume of data in the measurement data 146 for regression and computational analysis.

In some embodiments, the detector assembly 140 may further comprise a substrate 142. The two-dimensional sensor array 144 may be disposed on the substrate 142. Alternatively, the two-dimensional sensor array 144 may be at least partially embedded in the substrate 142. In some embodiments, the detector assembly 140 may further comprise a glass panel 145, as shown in FIG. 5. The two-dimensional microlens array 143 may be defined in the glass panel 145. For example, each microlens 148 of the two-dimensional microlens array 143 may be etched into the glass panel 145.

In some embodiments, a ratio of a number of sensors 147 in the two-dimensional sensor array 144 to a number of microlenses 148 in the two-dimensional microlens array 143 may be 1 to 1. In other words, for each pixel 141 of the detector assembly 140 may include a single sensor 147 and a single microlens 148, as shown in FIG. 3 and FIG. 4. In some embodiments, a ratio of a number of sensors 147 in the two-dimensional sensor array 144 to a number of microlenses 148 in the two-dimensional microlens array 143 may be at least 4 to 1. For example, as shown in FIG. 6, a single microlens 148 may cover four pixels 141 and sensors 147 of the two-dimensional sensor array 144. A single microlens 148 may alternatively cover additional pixels 141 and sensors 147 (e.g., 9, 6, 25, etc.).

The system 100 may further comprise a processor 150. The processor 150 may include a microprocessor, a microcontroller, field programmable gate array (FPGA), or other devices. The processor 150 may be coupled to the components of the system 100 in any suitable manner (e.g., via one or more transmission media, which may include wired and/or wireless transmission media) such that the processor 150 can receive output. The processor 150 may be configured to perform a number of functions using the output. An inspection tool can receive instructions or other information from the processor 150. The processor 150 optionally may be in electronic communication with another inspection tool, a metrology tool, a repair tool, or a review tool (not illustrated) to receive additional information or send instructions.

The processor 150 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 150 may be disposed in or otherwise part of the system 100 or another device. In an example, the processor 150 may be part of a standalone control unit or in a centralized quality control unit. Multiple processors 150 may be used, defining multiple subsystems of the system 100.

The processor 150 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 150 to implement various methods and functions may be stored in readable storage media, such as a memory.

If the system 100 includes more than one subsystem, then the different processors 150 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 150 may be configured to perform a number of functions using the output of the system 100 or other output. For instance, the processor 150 may be configured to send the output to an electronic data storage unit or another storage medium. The processor 150 may be further configured as described herein.

The processor 150 may be configured according to any of the embodiments described herein. The processor 150 also may be configured to perform other functions or additional steps using the output of the system 100 or using images or data from other sources.

The processor 150 may be communicatively coupled to any of the various components or sub-systems of system 100 in any manner known in the art. Moreover, the processor 150 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 150 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 150 (or computer subsystem) or, alternatively, multiple processors 150 (or multiple computer subsystems). Moreover, different sub-systems of the system 100 may include one or more computing or logic systems. Therefore, the above description should not be interpreted as a limitation on the present disclosure but merely an illustration.

The processor 150 may be in electronic communication with the light source 110. For example, the processor 150 may be configured to send instructions to the light source 110 to emit the light 111 to illuminate the workpiece 101.

The processor 150 may be in electronic communication with the detector assembly 140. The processor 150 may be configured to receive the measurement data 146 from each sensor 147 and a corresponding location of each sensor 147 in the two-dimensional sensor array 144. The processor 150 may be further configured to determine a spectroscopic critical dimension (SCD) of the workpiece 101 based on the measurement data 146 generated across the two-dimensional sensor array 144 and the corresponding location of each sensor 147. In some embodiments, the SCD of the workpiece 101 may comprise a deep-trench structure, a copper dishing, or other feature of the workpiece 101. The processor 150 may be further configured to determine azimuth angle and angle of incidence information based on the measurement data 146 generated across the two-dimensional sensor array 144 and the corresponding location of each sensor 147.

With the system 100, the two-dimensional sensor array 144 may be configured to more robustly capture the photons deviating from the chief ray of the light 112 reflected by the workpiece 101 (e.g., including diffracted rays 113). In addition, the two-dimensional microlens array 143 may be configured to maximize probabilities of capturing stray photons. Each pixel 141 of the two-dimensional sensor array 144 may be calibrated to one specific wavelength, and the corresponding micron lens 148 can have simultaneous angular and AOI information for the said wavelength, thereby leading to a more complete spectral description of the CD structure of the workpiece 101.

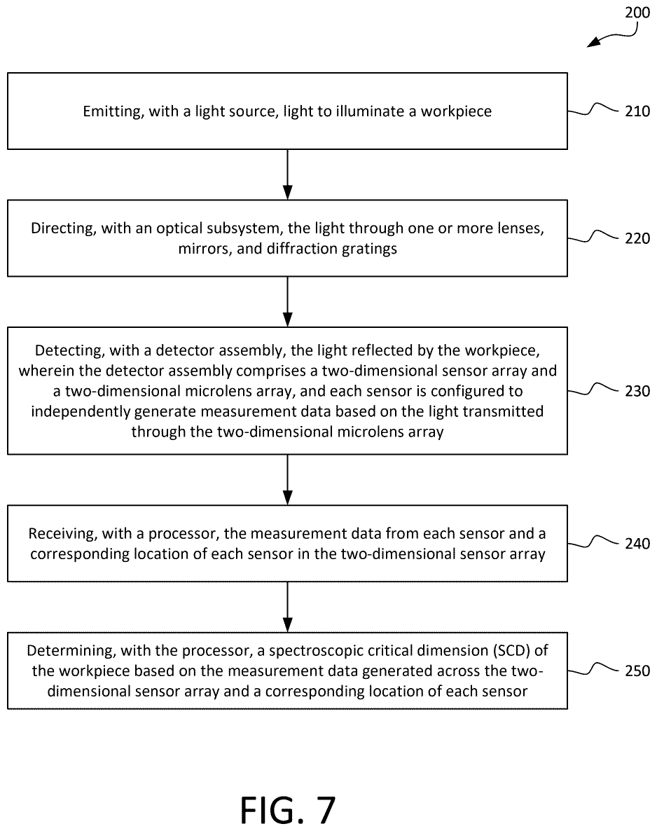

Another embodiment of the present disclosure provides a method 200. As shown in FIG. 7, the method 200 may comprise the following steps.

At step 210, a light source emits light to illuminate a workpiece.

At step 220, an optical subsystem directs the light through one or more lenses, mirrors, and diffraction gratings.

At step 230, a detector assembly detects the light reflected by the workpiece. The detector assembly may comprise a two-dimensional sensor array and a two-dimensional microlens array. Each sensor may be configured to independently generate measurement data based on the light transmitted through the two-dimensional microlens array.

At step 240, a processor receives the measurement data from each sensor and a corresponding location of each sensor in the two-dimensional sensor array.

At step 250, the processor determines a spectroscopic critical dimension (SCD) of the workpiece based on the measurement data generated across the two-dimensional sensor array and a corresponding location of each sensor.

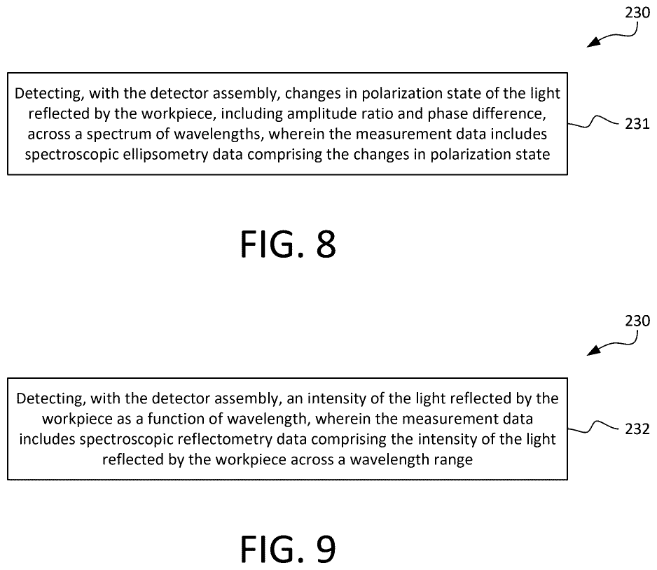

In some embodiments, the method 200 may be performed by a spectroscopic ellipsometry tool, such as, for example, the SE tool 100a described above and shown in FIG. 1. In this case, the optical subsystem may further comprise one or more compensators configured to polarize the light emitted by the light source. As shown in FIG. 8, step 230 may comprise step 231. At step 231, the detector assembly detects changes in polarization state of the light reflected by the workpiece, including amplitude ratio and phase difference, across a spectrum of wavelengths. The measurement data generated by each sensor may include spectroscopic ellipsometry data comprising the changes in polarization state.

In some embodiments, the method 200 may be performed by a spectroscopic reflectometry tool, such as, for example, the SR tool 100b described above and shown in FIG. 2. In this case, step 230 may comprise step 232, as shown in FIG. 9. At step 232, the detector assembly detects an intensity of the light reflected by the workpiece as a function of wavelength. The measurement data generated by each sensor may include spectroscopic reflectometry data comprising the intensity of the light reflected by the workpiece across a wavelength range.

With the method 200, the two-dimensional sensor array may be configured to more robustly capture the photons deviating from the chief ray of the light reflected by the workpiece 101 (e.g., including diffracted rays). In addition, the two-dimensional microlens array may be configured to maximize probabilities of capturing stray photons. Each pixel of the two-dimensional sensor array may be calibrated to one specific wavelength, and the corresponding micron lens can have simultaneous angular and AOI information for the said wavelength, thereby leading to a more complete spectral description of the CD structure of the workpiece.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a light source configured to emit light to illuminate a workpiece;
an optical subsystem comprising one or more lenses, mirrors, and diffraction gratings configured to direct and manipulate the light reflected by the workpiece;
a detector assembly configured to detect the light reflected by the workpiece, wherein the detector assembly comprises a two-dimensional sensor array and a two-dimensional microlens array, and each sensor is configured to independently generate measurement data based on the light transmitted through the two-dimensional microlens array; and
a processor in electronic communication with the detector assembly, wherein the processor is configured to:
receive the measurement data from each sensor and a corresponding location of each sensor in the two-dimensional sensor array; and
determine a spectroscopic critical dimension (SCD) of the workpiece based on the measurement data generated across the two-dimensional sensor array and the corresponding location of each sensor.

2. The system of claim 1, wherein the detector assembly further comprises a substrate, and the two-dimensional sensor array is disposed on or at least partially embedded in the substrate.

3. The system of claim 1, wherein the detector assembly further comprises a glass panel, and the two-dimensional microlens array is defined in the glass panel.

4. The system of claim 1, wherein the two-dimensional microlens array is coupled to the two-dimensional sensor array.

5. The system of claim 1, wherein the two-dimensional microlens array is separated from the two-dimensional sensor array.

6. The system of claim 1, wherein the two-dimensional sensor array comprises at least 500 by 500 sensors.

7. The system of claim 1, wherein a ratio of a number of sensors in the two-dimensional sensor array to a number of microlenses in the two-dimensional microlens array is 1 to 1.

8. The system of claim 1, wherein a ratio of a number of sensors in the two-dimensional sensor array to a number of microlenses in the two-dimensional microlens array is at least 4 to 1.

9. The system of claim 1, wherein each sensor of the two-dimensional sensor array is a charge coupled device (CCD) or a complementary metal oxide semiconductor (CMOS) sensor.

10. The system of claim 1, wherein each sensor of the two-dimensional sensor array is a tricolor RGB sensor.

11. The system of claim 1, wherein the processor is further configured to determine azimuth angle and angle of incidence information based on the measurement data generated across the two-dimensional sensor array and the corresponding location of each sensor.

12. The system of claim 1, wherein the optical subsystem further comprises one or more compensators configured to polarize the light emitted by the light source, the detector assembly is further configured to detect changes in polarization state of the light reflected by the workpiece, including amplitude ratio and phase difference, across a spectrum of wavelengths, and the measurement data includes spectroscopic ellipsometry data comprising the changes in polarization state.

13. The system of claim 1, wherein the detector assembly is further configured to detect an intensity of the light reflected by the workpiece as a function of wavelength, and the measurement data includes spectroscopic reflectometry data comprising the intensity of the light reflected by the workpiece across a wavelength range.

14. A method comprising:
emitting, with a light source, light to illuminate a workpiece;
directing, with an optical subsystem, the light through one or more lenses, mirrors, and diffraction gratings;
detecting, with a detector assembly, the light reflected by the workpiece, wherein the detector assembly comprises a two-dimensional sensor array and a two-dimensional microlens array, and each sensor is configured to independently generate measurement data based on the light transmitted through the two-dimensional microlens array;
receiving, with a processor, the measurement data from each sensor and a corresponding location of each sensor in the two-dimensional sensor array; and
determining, with the processor, a spectroscopic critical dimension (SCD) of the workpiece based on the measurement data generated across the two-dimensional sensor array and a corresponding location of each sensor.

15. The method of claim 14, wherein detecting, with the detector assembly, the light reflected by the workpiece comprises:
detecting, with the detector assembly, changes in polarization state of the light reflected by the workpiece, including amplitude ratio and phase difference, across a spectrum of wavelengths, wherein the measurement data includes spectroscopic ellipsometry data comprising the changes in polarization state.

16. The method of claim 14, wherein detecting, with the detector assembly, the light reflected by the workpiece comprises:
detecting, with the detector assembly, an intensity of the light reflected by the workpiece as a function of wavelength, wherein the measurement data includes spectroscopic reflectometry data comprising the intensity of the light reflected by the workpiece across a wavelength range.

17. The method of claim 14, wherein a ratio of a number of sensors in the two-dimensional sensor array to a number of microlenses in the two-dimensional microlens array is 1 to 1.

18. The method of claim 14, wherein a ratio of a number of sensors in the two-dimensional sensor array to a number of microlenses in the two-dimensional microlens array is at least 4 to 1.

19. The method of claim 14, wherein each sensor of the two-dimensional sensor array is a charge coupled device (CCD) or a complementary metal oxide semiconductor (CMOS) sensor.

20. The method of claim 14, wherein each sensor of the two-dimensional sensor array is a tricolor RGB sensor.
